(19) United States
(12) Patent Application Publication
(10) Pub. No.: US 2014/0321053 A1
(43) Pub. Date: Oct. 30, 2014

(54) Temperature Regulation Via Immersion In A Liquid

(71) Applicants: Brian G. Donnelly, Swords (IE); Nick P. Jeffers, Dublin (IE); Jason Stafford, Wexford (IE); Ollie Burns, Meath (IE)

(72) Inventors: Brian G. Donnelly, Swords (IE); Nick P. Jeffers, Dublin (IE); Jason Stafford, Wexford (IE); Ollie Burns, Meath (IE)

(21) Appl. No.: 13/930,452

(22) Filed: Jun. 28, 2013

Related U.S. Application Data
(60) Provisional application No. 61/817,281, filed on Apr. 29, 2013.

(51) Int. Cl. H05K 7/20

(52) U.S. Cl. CPC H05K 7/20381; H05K 7/20209; H05K 2007/20527
USPC 361/691; 261/77; 261/32

(57) ABSTRACT

An apparatus includes a reservoir, a structure, and one or more metal tubes. The reservoir is configured to hold a volume of liquid therein and, has a wall area with a metal cross section. The structure has a distribution of injectors. Each injector is configured to inject gas bubbles into said volume of liquid in a bottom portion of the reservoir. The one or more metal tubes traverse a part of the reservoir. Each metal tube is capable of carrying a gas flow.

This application claims the benefit of provisional application 61/817281, filed Apr. 29, 2013.

### BACKGROUND

1. Technical Field

The invention relates to apparatus for temperature regulation and methods for providing temperature regulation.

2. Discussion of the Related Art

This section introduces aspects that may be helpful to facilitating a better understanding of the inventions. Accordingly, the statements of this section are to be read in this light and are not to be understood as admissions about what is in the prior art or what is not in the prior art.

Active electrical and optical devices generate heat, which must, in some cases, be dissipated via specialized cooling systems. The cooling systems may use solid structures, air, liquid, two-phase coolant, and/or other materials to transport heat away from the optical and/or active electronic devices. In such cooling systems, a hot liquid or two-phase coolant may be cooled to enable the liquid or two-phased coolant to absorb and transport away additional heat, e.g., in a closed loop system.

### SUMMARY OF SOME ILLUSTRATIVE EMBODIMENTS

An embodiment of an apparatus includes a reservoir, a structure, and one or more metal tubes. The reservoir is configured to hold a volume of liquid therein and, has a wall area with a metal cross section. The structure has a distribution of injectors. Each injector is configured to inject gas bubbles into said volume of liquid in a bottom portion of the reservoir. The one or more metal tubes traverse a part of the reservoir. Each metal tube is capable of carrying a gas flow.

In any of the above embodiments, an exterior metal portion of the reservoir may have metal fins thereon.

In some embodiments, the above apparatus may further include a pump connected to force the gas flow through the one or more metal tubes and a plurality of fans located to force air to flow along a metal exterior portion of the reservoir. In some such embodiments, one of the fans may have a piezoelectric driver and be located in a cavity between first ends of a first set of the metal fins and second ends of a second set of the fins, wherein the fins of the first and second sets are substantially parallel at the first and second ends.

In any of the above embodiments, the apparatus may further include a device connected to return the gas from the bubbles from a free top surface of the volume of liquid to the structure.

In any of the above embodiments, the apparatus may further comprise a device configured to hold one or more optical or active electronic devices in the reservoir for immersion in the volume of liquid.

In any of the above embodiments, the structure may be configured to form some of the gas bubbles to have diameters of three millimeters or more. For example, the structure may be configured to form some of the bubbles to have diameters of five to eight millimeters in the volume of liquid.

In any of the above embodiments, the one or more metal tubes may have corrugated walls.

An embodiment of a method includes operating one or more optical or active electronic devices while the one or more optical or active electronic devices are immersed in a volume of liquid held in a reservoir. During said operating, the method includes injecting gas bubbles into the volume of liquid such that the gas bubbles rise through and mix the liquid. During the operating, the method includes changing the temperature of the liquid by flowing a gas along an external surface of said reservoir and/or flowing a gas through one or more metal tube segments located in said volume of liquid.

In some embodiments of the method, said producing includes producing some of the gas bubbles to have diameters of three or more millimeters in the liquid.

In any embodiments of the method, each metal tube segment may be corrugated.

In any embodiments of the method, the changing a temperature may include cooling said liquid.

In any embodiments of the method, said changing a temperature may include causing gas to flow between metal fins located on the external surface of the reservoir by operating a fan located between some of said fins.

In any embodiments of the method, the changing a temperature may include both flowing a gas along an external surface of said reservoir and flowing a gas through the metal tube segments located in said volume of liquid.

In any embodiments of the above methods, the act of changing a temperature may include cooling the liquid.

### BRIEF DESCRIPTION OF THE FIGURES

FIG. 1A is a vertical cross-sectional view illustrating a first embodiment of an apparatus for temperature-regulating one or more optical or active electronic devices via immersion of the one or more optical or active electronic devices in a liquid;

FIG. 1B is a vertical cross-sectional view illustrating a second embodiment of an apparatus configured for temperature-regulating one or more optical or active electronic devices via immersion of the one or more optical or active electronic devices in a liquid;

FIG. 1C is a vertical cross-sectional view illustrating a third embodiment of an apparatus for temperature-regulating one or more optical or active electronic devices via immersion of the one or more optical or active electronic devices in a liquid;

FIG. 2A is a horizontal cross-sectional view illustrating the array of injectors and an external active heat-transfer system of the apparatus of FIG. 1A;

FIG. 2B is a horizontal cross-sectional view illustrating the array of injectors and an internal active heat-transfer system of the apparatus of FIG. 1B;

FIG. 2C is a horizontal cross-sectional view illustrating the array of injectors and the external and internal active heat transfer systems of the apparatus of FIG. 1C;

FIG. 3 is a face view illustrating a portion of the external active heat-transfer system on the outer surface of the reservoir of FIGS. 1A, 1C, 2A and 2C;

FIG. 4 is an oblique cut-away view of a portion of the reservoir of FIGS. 1A and 2A illustrating a porous object embodiment of the structure with the array of injectors; and

FIG. 5 is a flow chart that schematically illustrates a method for regulating a temperature of one or more optical or active electronic components via immersion in a volume of liquid, e.g., with the apparatus of FIGS. 1A-1C and 2A-2C.

In the Figures and text, like reference numbers refer to structurally and/or functionally similar elements.

In the Figures, relative dimensions of some features may be exaggerated to more clearly show one or more of the structures being illustrated therein.

Herein, various embodiments are described more fully by the Figures and the Detailed Description of Illustrative Embodiments. Nevertheless, the inventions may be embodied in various forms and are not limited to the specific embodiments that are described in the Figures and Detailed Description of Illustrative Embodiments.

### DESCRIPTION OF THE ILLUSTRATIVE EMBODIMENTS

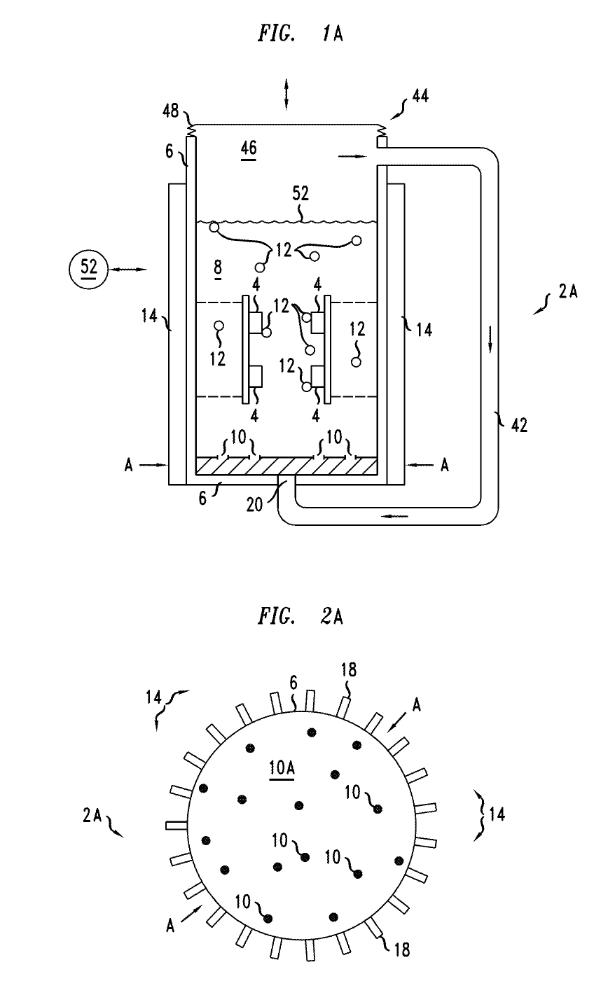

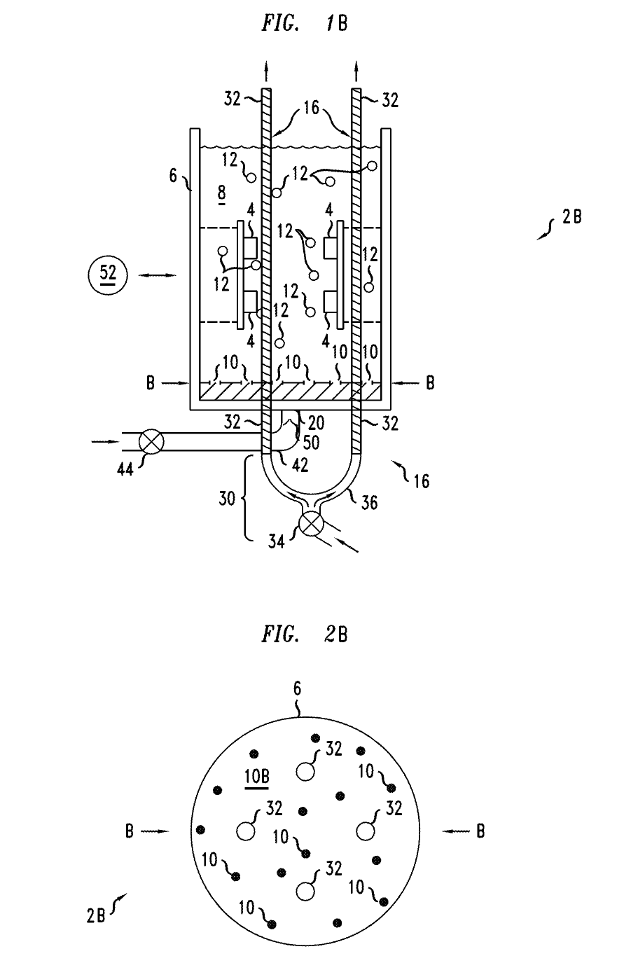

FIGS. 1A, 1B, and 1C illustrate apparatus 2A, 2B, 2C configured to perform temperature-regulation of one or more optical and/or active electronic devices 4 with temperature-dependent operating characteristics. The temperature regulation may involve temperature stabilization, cooling, and/or heating of the one or more optical and/or active electronic devices 4. In embodiments where the one or more devices 4 include optical apparatus, such apparatus 4 may have an output wavelength or routing wavelength that varies with temperature. In embodiments where the one or more devices 4 are active electronics, such electronics may generate heat during operation. In various embodiments, such an optical or active electronic device 4 may operate improperly at temperatures, which are too high and/or too low, and/or may be damaged when operated at temperatures, which are too high or too low. Examples of the one or more optical and/or active electronic devices 4 may include planar optical waveguide circuits, lasers, optical amplifiers, and/or active electronic devices such as electronic amplifiers, optical and electrical transmitters and optical and electrical receivers. Some such optical and/or active electronic devices 4 may include an array of the above-described optical and/or active electronic devices, which are mounted on one or more circuit boards, optical and/or electronic substrates, or other structures.

Each apparatus 2A, 2B, 2C includes a reservoir 6, a volume 8 of liquid, a structure having an array of injectors 10 of gas bubbles 12, and external and/or internal active heat-transfer systems 14, 16. Herein, an internal active heat-transfer system is substantially surrounded by a volume of liquid in a reservoir and, an external active heat-transfer system is located outside of the volume of liquid and outside of the reservoir.

The reservoir 6 is constructed to hold the volume 8 of liquid without leakage when positioned in an upright position. The wall portions of the reservoir 6 are impermeable to the liquid and any port(s) along bottom or lower side portions of the reservoir 6 are configured to impede leakage of the liquid. The reservoir 6 may or may not be closed at the top.

The reservoir 6 is primarily fabricated of a material with a relatively high thermal conductivity. For example, wall portions of the reservoir 6 may be primarily constructed of a metal such as aluminum. For example, large areas of the reservoir may have metal cross sections, e.g., the reservoir 6 may have metal side wall(s). Such thermally conductive embodiments of the reservoir 6 can readily transfer heat between the volume 8 of liquid in the reservoir 6 and the exterior ambient, e.g., air.

The volume 8 of liquid is a heat-transfer medium capable of absorbing heat from and/or transferring heat to the one or more optical and/or active electronic devices 4 in the volume 8, i.e., at high transfer rates. The liquid may be a polar liquid, e.g., water, or a suitable dielectric liquid, e.g., a hydro-fluorocarbon (HFC) refrigerant liquid such as 1,1,1,2-Tetrafluoroethane, which is also known as R134a. The liquid preferably has a high heat capacity. Also, the liquid typically has a low or moderate viscosity so that buoyancy forces move the gas bubbles 12 through the volume 8 of liquid coolant at a speed that can provide significant bubble-induced mixing of the liquid.

The one or more optical and/or active electronic devices 4 are immersed in the volume 8 of liquid, e.g., surrounded by and typically in close physical contact with the liquid, e.g., across hermetic packages. The one or more optical and/or active electronic devices 4 may be, e.g., either loosely or rigidly physically positioned in the volume 8 of liquid. The one or more optical and/or active electronic devices 4 may be held in position inside the volume 8 of liquid by positioning devices such as wires, screws, clamps, and/or rigid braces. Such positioning devices are schematically illustrated by dashed lines in FIGS. 1A-1C. The immersion of the one or more optical and/or active electronic devices 4 in the liquid provides heat-transfer that enables the temperature-regulation of the one or more optical and/or active electronic devices 4. While the volume 8 of liquid regulates the temperature of the one or more optical and/or active electronic devices 4, one or more other elements regulate the temperature of the liquid as discussed herein.

The structure with the array of injectors 10 is located in a lower portion of the reservoir 6, e.g., along the bottom and/or lower side wall(s) of the reservoir 6. The individual injectors 10 are configured to inject the gas bubbles 12 into the volume 8 of liquid. The injected gas bubbles 12 rise through the liquid due to their buoyancy and injection velocity and mix the liquid of the volume 8 during their rising motion therein. In the structure, some of the injectors 10 are constructed to generate the gas bubbles 12 with large diameters so that their rising motion will substantially mix the liquid of the volume 8. For example, such large bubbles 12 may have diameters of three millimeters or more and may even have diameters of five to eight millimeters. The rising motion of such large bubbles 12 can cause large displacements of the liquid in the volume 8 and significant vortex generation in the liquid of the volume 8.

The mixing may better homogenize the temperature of the liquid in the volume 8 and/or may break up boundary layers of the liquid along hard objects. For example, some of the injectors 10 may be constructed and placed to specifically direct some large ones of the gas bubbles 12 towards the one or more optical and/or active electronic devices 4 or towards the side wall(s) of the reservoir 6. The rising motion of these gas bubbles 12 may disrupt boundary layer(s) of the liquid at the one or more optical and/or active electronic devices 4 or at the side wall(s) of the reservoir 6. Disrupting such boundary layers of the liquid can also increase the heat-transfer rate between the one or more optical and/or active electronic devices 4 and the liquid and/or increase the heat-transfer rate between the liquid and the side wall(s) of the reservoir 6.

The injectors 10 may also be constructed or laterally distributed so that the gas bubbles 12 are laterally dispersed through horizontal cross sections of the volume 8 of the liquid. For example, the lateral distribution of the injectors 10 may be approximately uniform along the bottom of the reservoir 6 or may be approximately random along the bottom of the reservoir. Such distributions of the injectors 10 may produce lateral distributions of the bubbles 12 that augment convection flows through the interior of the volume 8 of the liquid and increase heat-transfer rates through the volume 8 of liquid.

Thus, the injector-produced gas bubbles 12 cause substantial mixing of the liquid of the volume 8 and can increase the overall heat-transfer rate between the exterior ambient and the one or more optical and/or active electronic devices 4 with respect to the heat-transfer rate available in the absence of such mixing. For example, the bubble-motion-induced mixing may increase the heat-transfer rate over the rate available through diffusion alone.

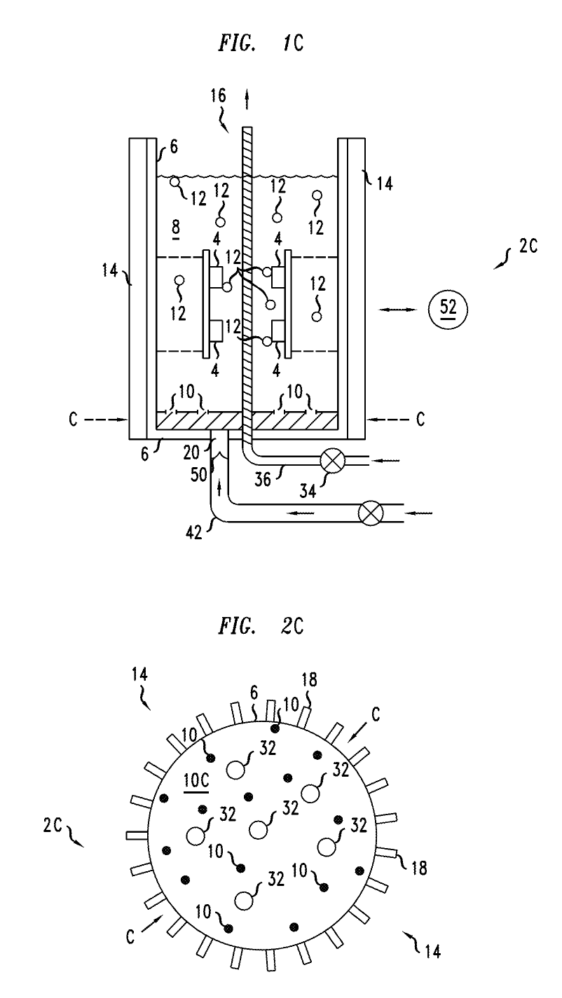

FIGS. 2A, 2B, and 2C illustrate the structure with the array of injectors 10 and the external and internal active heat-transfer systems 14, 16 at cross sections of the apparatus 2A-2C at AA, BB, and CC in FIGS. 1A-1C.

FIG. 2A shows an example gas-flow disrupter embodiment of the structure with the array of injectors 10 in FIG. 1A. The gas-flow disrupter spatially segregates the gas-flow received from one or more gas input ports 20, i.e., in FIG. 1A, into individual gas flows into the bottom of the reservoir 6. The individual gas flows form the gas bubbles 12 that rise in the volume 8 of liquid of FIG. 1A thereby mixing said liquid.

The gas-flow disrupter may be formed by a solid layer 10A that has a lateral spatial distribution of holes there through, e.g., an about uniform or an about random distribution of such holes. The holes are indicated by black dots in FIG. 2A. The solid layer 10A causes the gas received from the one or more gas input ports 20 to pass through the individual holes thereby restricting the gas flow to form laterally separated gas streams. The holes are selectively arranged so that the resulting gas streams form gas bubbles 12 having appropriate lateral distributions and sizes near the bottom of the volume 8 of liquid in FIG. 1A. The solid layer 10A may be formed by a wire mesh or a planar layer with a suitable distribution of such through holes therein.

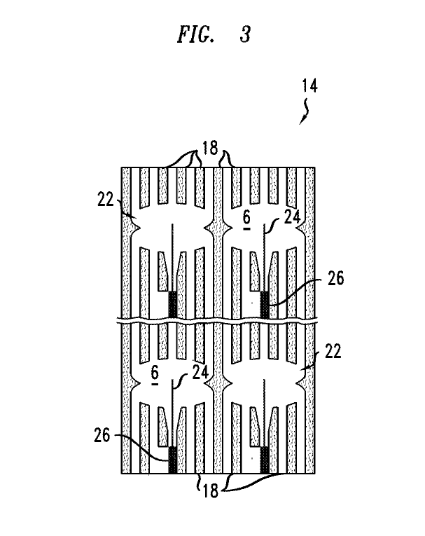

FIG. 2A also illustrates the external active heat-transfer system 14, which is located outside and on the outer surface of the reservoir 6 in FIG. 1A. A local region of the outer surface of the reservoir 6 and the external active heat-transfer system 14 thereon is shown in FIG. 3.

Referring to FIG. 3, the external active heat-transfer system 14 includes thermally conductive fins 18 and piezo-electric fans 22. The conductive fins 18 may form substantially parallel arrays and may be primarily made of a highly thermally conductive material such as a metal. Each piezo-electric fan 22 includes a fan blade 24 and a piezo-electric driver 26. Each fan blade 24 is capable of flexing, e.g., in a plane locally tangent to the outer surface of the reservoir 6 in response to being mechanically driven. Each piezo-electric driver 26 is physically connected to drive the corresponding fan blade 24 to oscillate, e.g., approximately in a plane tangent to the local portion of the outer surface of the reservoir 6. The piezo-electric fans 22 may be, e.g., located between the arrays of conductive fins 18 and may be constructed to produce air currents that flow between the conductive fins 18. As illustrated, the fan blades 24 may be located in cavities between the conductive fins 18 so that the oscillating fan blades 24 efficiently force air between adjacent ends of the conductive fins 18, e.g., to produce air flows along the conductive fins 18. Also, the conductive fins 18 may be approximately parallel at opposite sides of the cavities to facilitate such air flows. Examples of such combinations of parallel arrays of conductive fins and piezo-electric fans may be described, e.g., in U.S. patent application Ser. No. 13/757,006, filed Feb. 1, 2013, which is incorporated herein by reference in its entirety.

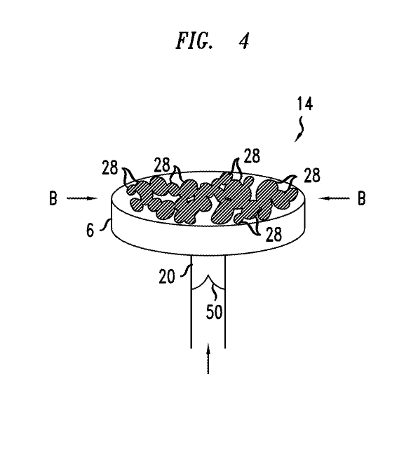

FIG. 4 illustrates a porous structure that may be used to form an alternate embodiment of the gas-flow disrupter 10A of FIG. 2A. The porous structure 10A is formed by small objects 28 that are packed or bonded together to form a solid mass that covers the bottom of the reservoir 6. The mass causes an input gas flow, e.g., an air flow, which is received from the port(s) 20, to be broken up into smaller flows. The individual smaller flows produce the gas bubbles 12 with appropriate size and lateral distribution in the volume 8 of liquid of FIG. 1A.

FIG. 2B shows an embodiment of a gas-flow disrupter 10B for use in the structure with the array of injectors 10 of FIG. 1B. The gas-flow disrupter 10B includes either hole-perforated layer or a porous structure, which is similar to the gas-flow disrupter 10A of FIGS. 2A and 4. The gas-flow disrupter 10B spatially segregates a gas flow received from the one or more ports 20 into laterally separated flows thereby producing the gas bubbles 12 in the volume 8 of liquid near the bottom of the reservoir 6. In the gas-flow disrupter 10B, through holes or through pores, which are indicated by black dots in FIG. 2A, function as the injectors 10. The through holes or pores may be substantially randomly located to form a quasi-uniform lateral distribution along the upper surface of the gas-flow disrupter.

FIGS. 1B and 2B also illustrate portions of the internal active heat-transfer system 16 of FIG. 1B. The internal active heat-transfer system 16 has heat-transfer surfaces located within the reservoir 6. The internal active heat-transfer system 16 includes an air delivery system 30 and one or more conductive tubes 32. The air delivery system typically includes an air pump 34 and an air coupler 36, which connects an exhaust of the air pump 34 to the one or more conductive tubes 32. The one or more conductive tubes 32 have segments, which are located in the reservoir 6 and are laterally surrounded by the liquid of the volume 8. The liquid of the volume 8 of liquid is in direct physical contact with and can transfer heat to these segments of the one or more conductive tubes 32. Thus, the internal active heat-transfer system 16 provides surfaces in the interior of the reservoir 6 for the direct transfer of heat to and/or from the liquid of the volume 8.

In some embodiments, the conductive tubes 32 may have corrugated surfaces to provide larger surfaces for heat-transfer rate between air flowing therein and the adjacent liquid of the volume 8. The segments of the conductive tubes 32 located in the liquid of the volume 8 may be primarily or completely formed of a highly conductive material such as a metal.

FIGS. 1C and 2C illustrates apparatus 2C, which includes both the internal and the external active heat-transfer systems 16, 14 of FIGS. 1B and 1A. In FIG. 2C, the injectors 10 are indicated by black dots, and the conductive tubes 32 of the internal active heat-transfer system 16 are indicated by empty circles. In the apparatus 2C, the various elements and features 4, 6, 8, 10, 12, 14, 16, 20, 32, 34, 36, have forms and functions as described with respect to the apparatus 2A-2B of FIGS. 1A, 1B, 2A, 2B, 3, and 4.

In some embodiments, the structure with the array of injectors 10 of FIGS. 1A-1C may have a vertical sequence of the individual gas-flow disrupters 10A, 10B of FIGS. 2A-2B.

In FIGS. 1A-1C, the structure with the array of injectors 10 receives a gas flow from one or more ports 20 located along the bottom and/or lower portion of the side(s) of the reservoir 6. The one or more ports 20 connect via tube(s) 42 to one or more pumps 44, which produce a gas flow to the gas-flow disrupter 10A, 10B, 10C. The gas may flow may be in a closed system, as illustrated in FIG. 1A, or may be in an open system, as illustrated in FIGS. 1B-1C.

In FIG. 1A, the illustrated embodiment of the pump 44 includes a chamber 46 closing and hermetically sealing the top of the reservoir 6 and also includes a controllable diaphragm 48, which is located along one surface of the chamber 46. The controllable diaphragm 48 may be moved to force gas, released as the gas bubbles 12 burst at the free top surface 52 of the volume 8 of liquid, into the tube 42. That is, the motion of the controllable diaphragm returns such released gas via the tube 42 to the port 20 for re-injection into the bottom of the volume 8 of liquid. That is, the illustrated embodiment of the pump 44 provides a closed system for the gas used to produce the gas bubbles 12.

In FIG. 1A, the controllable diaphragm 48 may be moved, as indicated by the double-headed arrow. Such movement of the controllable diaphragm 48 may be caused and controlled by a convention mechanical motor and control device (not shown in FIG. 1A). Persons of ordinary skill in the relevant arts would readily understand how to make and use such motors and devices in the apparatus 2A from the present disclosure.

In FIGS. 1B-1C, the pump(s) 44 may force ambient air into the tube(s) 42 that connect to the one or more ports 20. The tube(s) 42 may include one-way valve(s) 50 to allow fluid to only pass through the one or more ports 20 in a single direction. That is, the one-way valve(s) 50 are configured to only allow gas to be forced into the structure with the array of injectors 10 from the tube(s) 42. Such one-way valve(s) 50 do not allow liquid of the volume 8 to leak from the reservoir 6.

Alternately, in FIG. 1A, the tube 42 may forms a chimney whose height stops leakage of liquid of the volume 8 from the reservoir 6 in the absence of a back pressure from the one or more pumps 44.

In FIGS. 1A-1C, the structure with the array of injectors 10, e.g., the gas-flow disrupters 10A-10C of FIGS. 2A-2C, may be constructed to produce some of the gas bubbles 12 to have diameters of three or more millimeters or even to have diameters of five to eight millimeters in the volume 8 of liquid of FIG. 1. Such gas bubbles 12 of large size may better mix the liquid of the volume 8, e.g., because their rising motion may readily generate vortices in the liquid and/or effectively disrupt boundary layers of the liquid in the reservoir. To obtain such desirable results, the inventors believe that the liquid of the volume 8 should have a Reynolds number that is greater than about 200. In addition, it is often advantageous that the injectors 10 have average diameters of about 0.5 millimeters or more, e.g., if the volume 8 holds a polar liquid such as water, a dielectric liquid such as HFC, or another liquid of similar viscosity.

Referring to FIGS. 1A-1C, the apparatus 2A-2C may optionally include an electronic controller 52 that controls and/or stabilizes the temperature of the volume 8 of liquid. The electronic controller 52 may, e.g., indirectly or directly monitor the temperature of the liquid and control the operation of the external and/or internal active heat-exchange systems 14, 16 to maintain that temperature in a selected operating range. Such control by the electronic controller 52 may include operating the external and/or internal active heat-exchange systems 14, 16 to heat and/or to cool the volume 8 of liquid.

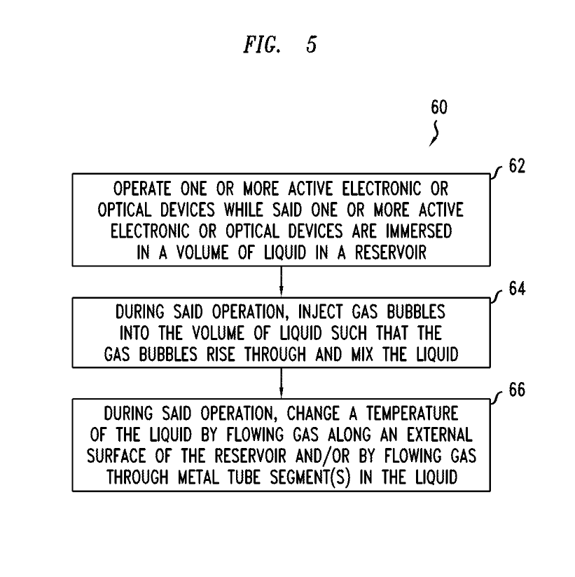

FIG. 5 schematically illustrates a method 60 for temperature regulating via immersion of optical and/or active electronic device(s) in a volume of liquid, e.g., the volume 8 of liquid in the reservoir 6 as illustrated in FIGS. 1A-1C.

The method 60 includes operating one or more optical or active electronic devices while said one or more optical or active electronic devices are immersed in a volume of liquid that is located in a holding reservoir (step 62). The one or more optical or active electronic devices may be, e.g., the optical and/or active electronic device(s) 4 of FIGS. 1A-1C.

The method 60 includes injecting gas bubbles into a bottom portion of the volume of liquid, while performing the step 62 of operating the one or more optical or active electronic devices, such that the gas bubbles rise through and mix the liquid of the volume (step 64). The bubbles may be, e.g., the gas bubbles 12 injected into the bottom of the reservoir 6 by the injectors 10 as illustrated in FIGS. 1A-1C.

The method 60 includes regulating the temperature of the liquid of the volume by flowing gas along an external surface of said reservoir and/or flowing gas through metal tube segment(s) located in said volume of liquid (step 66). Such a temperature-regulating gas flow may be produced, e.g., by the external and/or internal active heat-exchange systems 14, 16 of FIGS. 1A-1C.

In various embodiments, the method 60 may include producing some of the gas bubbles to have diameters of three or more millimeters in the liquid, e.g., diameters of about 5 to 8 millimeters, to provide adequate mixing of the liquid. Such mixing may, e.g., disrupt the boundary layers of liquid at hard surfaces in the reservoir and/or product convection currents in the liquid of the volume.

In various embodiments of the method 60, the metal tube segment(s) located in the volume of liquid may have corrugated wall(s), which can improve heat transfer due to an increased surface area-to-volume ratio.

In various embodiments of the method 60, the step 66 of flowing gas may include operating a fan to flow gas between metal fins on the external surface of the reservoir holding the liquid. The fan may be located between some of said fins and/or adjacent ends of parallel arrays of the fins, e.g., as illustrated in FIG. 4.

In various embodiments, the temperature regulation of the method 60 may involve temperature stabilizing, cooling, and/or heating the one or more optical or active electronic device(s) immersed in the volume of liquid. Such temperature regulation may be controlled by an external controller, e.g., the optional electronic controller 52 of FIGS. 1A-1C, which may perform temperature regulation based on direct or indirect feedback temperature measurements, e.g., measurements of the temperature of the liquid in the volume and/or of the one or more optical or active electronic devices immersed in the liquid.

The invention is intended to include other embodiments that would be obvious to one of skill in the art in light of the description, figures, and claims.

What we claim is:

1. An apparatus comprising:
a reservoir being configured to hold a volume of liquid therein and, having a wall area with a metal cross section;
a structure having a distribution of injectors, each injector being configured to inject gas bubbles into said volume of liquid in a bottom portion of the reservoir;
one or more metal tubes located to traverse a part of the reservoir; and
wherein each metal tube is capable of carrying a gas flow.

2. The apparatus of claim 1, further comprising:
a pump being connected to force the gas flow through the one or more metal tubes, and
a plurality of fans located to force air to flow along a metal exterior portion of the reservoir.

3. The apparatus of claim 1, wherein the structure is configured to form some of the gas bubbles to have diameters of three millimeters or more.

4. The apparatus of claim 2, wherein the structure is configured to form some of the gas bubbles to have diameters of three millimeters or more in the volume of liquid.

5. The apparatus of claim 1, wherein the one or more metal tubes have corrugated walls.

6. The apparatus of claim 2, wherein the one or more metal tubes have corrugated walls.

7. The apparatus of claim 1, wherein an exterior metal portion of the reservoir has metal fins thereon.

8. The apparatus of claim 2, wherein an exterior metal portion of the reservoir has metal fins thereon.

9. The apparatus of claim 7, wherein one of the fans has a piezoelectric driver and is located in a cavity between first ends of a first set of the metal fins and second ends of a second set of the fins, the fins of the first and second sets being substantially parallel at the first and second ends.

10. The apparatus of claim 7, wherein the one or more metal tubes have corrugated walls.

11. The apparatus of claim 1, further comprising a device connected to return gas from the gas bubbles from a free top surface of the volume of liquid to the structure.

12. The apparatus of claim 8, wherein the structure is configured to form some of the gas bubbles to have diameters of, at least, three millimeters in the volume of liquid.

13. The apparatus of claim 1, further comprising a device configured to hold one or more optical or active electronic devices immersed in the volume of liquid.

14. A method, comprising:
operating one or more optical or active electronic devices while said one or more optical or active electronic devices are immersed in a volume of liquid held in a reservoir;
during said operating, injecting gas bubbles into the volume of liquid such that the gas bubbles rise through and mix the liquid; and
during said operating, changing a temperature of the liquid by flowing a gas along an external surface of said reservoir or flowing a gas through one or more metal tube segments located in said volume of liquid.

15. The method of claim 14, wherein said injecting includes producing some of the gas bubbles to have diameters of three or more millimeters in the liquid.

16. The method of claim 14, wherein the changing a temperature of the liquid includes flowing a gas through one or more corrugated metal tube segments located in said volume of liquid.

17. The method of claim 14, wherein the changing a temperature includes cooling said liquid.

18. The method of claim 14, wherein said changing a temperature includes causing gas to flow between metal fins located on the external surface of the reservoir by operating a fan located between some of said fins.

19. The method of claim 15, wherein the changing a temperature includes both flowing a gas along an external surface of said reservoir and flowing a gas through the metal tube segments located in said volume of liquid.

20. The method of claim 19, wherein the changing a temperature includes cooling said liquid.
